(19) United States
(12) Patent Application Publication
(10) Pub. No.: US 2025/0006766 A1
(43) Pub. Date: Jan. 2, 2025

(54) Stacking Single-Photon Avalanche Diodes and High Voltage Devices

(71) Applicant: SEMICONDUCTOR COMPONENTS INDUSTRIES, LLC, Scottsdale, AZ (US)

(72) Inventors: Jeffrey Peter GAMBINO, Gresham, OR (US); Jaroslav PJENCAK, Dolni Becva (CZ); Radim SPETIK, Roznov pod Radhostem (CZ); Michael Gerard KEYES, Dromcollogher (IE); Vincenzo SESTA, Cork (IE); Moshe AGAM, Portland, OR (US)

(73) Assignee: SEMICONDUCTOR COMPONENTS INDUSTRIES, LLC, Scottsdale, AZ (US)

(21) Appl. No.: 18/341,825

(22) Filed: Jun. 27, 2023

(51) Int. Cl. H01L 27/146; G01S 7/481; H01L 23/00

(52) U.S. Cl. CPC H01L 27/14634; G01S 7/4816; H01L 24/08; H01L 24/80; H01L 27/14636; H01L 27/1469; H01L 2224/08145; H01L 2224/80895; H01L 2224/80896

(57) ABSTRACT

Circuitry is provided that includes a first die, a second die, and a third die that are vertically stacked. The second die may have a front side facing the third die and a back side facing the first die. The first die can include a plurality of single-photon avalanche diodes (SPADs). The second die can include a plurality of switches coupled to cathode terminals of the plurality of SPADs in the first die. The third die can include digital readout logic coupled to the plurality of switches in the second die. The plurality of switches in the second die can be power using a high voltage and are sometimes referred to as analog high voltage switches. The digital readout logic in the third die can be power using a voltage that is lower than the high voltage being used to power the second die.

### FIELD

This relates generally to imaging systems and, more specifically, to imaging systems with single-photon avalanche diodes (SPADs).

### BACKGROUND

A SPAD is a type of P-N junction diode biased above a breakdown voltage using a high voltage. In this state, the SPAD can be sensitive to a single impinging photon. A SPAD can be coupled to associated high voltage switches and digital readout circuits. The high voltage switches can include a pull-up transistor and a pull-down transistor. The digital readout circuits can include a comparator, level shifter, and pulse generators.

Conventionally, an array of SPADs and the high voltage switches are formed on separate chips or packages. In such configurations, it can be challenging to achieve active pixel quenching and to minimize package size while ensuring connection reliability. It is within this context that the embodiments described herein arise.

### BRIEF DESCRIPTION OF THE DRAWINGS

FIG. 1 is a functional block diagram of an illustrative SPAD-based imaging system in accordance with some embodiments.

FIG. 2 is a diagram of an illustrative vehicle having an imaging system of the type shown in FIG. 1 in accordance with some embodiments.

FIG. 3 is a schematic diagram of an illustrative SPAD pixel in accordance with some embodiments.

FIG. 4 is a cross-sectional side view of a sensor die, an analog high voltage die, and a digital readout logic die stacked vertically with respect to one another in accordance with some embodiments.

FIG. 5 is a cross-sectional side view of an illustrative n-type high voltage transistor in accordance with some embodiments.

FIG. 6 is a cross-sectional side view of an illustrative p-type high voltage transistor in accordance with some embodiments.

FIG. 7A is a cross-sectional side view showing frontside processing for a digital readout logic wafer and an analog high voltage wafer in accordance with some embodiments.

FIG. 7B is a cross-sectional side view showing wafer bonding between the digital readout logic wafer and the analog high voltage wafer in accordance with some embodiments.

FIG. 7C is a cross-sectional side view showing removal of a handling wafer at the back side of the analog high voltage wafer in accordance with some embodiments.

FIG. 7D is a cross-sectional side view showing additional backside processing for the analog high voltage wafer in accordance with some embodiments.

FIG. 7E is a cross-sectional side view showing frontside processing for a sensor wafer in accordance with some embodiments.

FIG. 7F is a cross-sectional side view showing wafer bonding between the sensor wafer and the processed back side of the analog high voltage wafer in accordance with some embodiments.

FIG. 7G is a cross-sectional side view showing backside processing for the sensor wafer in accordance with some embodiments.

FIG. 8 is a flow chart of illustrative steps for fabricating circuitry of the type shown in FIGS. 4-7 in accordance with some embodiments.

FIG. 9 is a cross-sectional side view of a sensor die, an analog high voltage die without any n-type transistors, and a digital readout logic die stacked vertically with respect to one another in accordance with some embodiments.

### DETAILED DESCRIPTION

Imaging systems or devices may include single-photon avalanche diodes (SPADs), forming SPAD-based imaging systems or devices (sometimes referred to herein simply as SPAD devices). SPAD-based devices are sometimes referred to as silicon photomultipliers (SiPMs).

Some imaging systems include image sensors that sense light by converting impinging photons into electrons or holes that are integrated (collected) in pixel photodiodes within the sensor array. After completion of an integration cycle, collected charge is converted into a voltage, which is supplied to the output terminals of the sensor. In complementary metal-oxide semiconductor (CMOS) image sensors, the charge to voltage conversion is accomplished directly in the pixels themselves and the analog pixel voltage is transferred to the output terminals through various pixel addressing and scanning schemes. The analog pixel voltage can also be later converted on-chip to a digital equivalent and processed in various ways in the digital domain.

SPAD devices, on the other hand, employ a different photon detection mechanism. In some illustrative configurations sometimes described herein as an example, SPAD devices may form light detection and ranging (LIDAR) devices or imaging systems. A LIDAR device may include a light source that emits light toward a target object or scene. A light sensing diode (SPAD) in the LIDAR device may be biased above its breakdown point and when an incident photon from the light source (e.g., light that has reflected off of the target object/scene) generates an electron-hole pair, these carriers initiate an avalanche breakdown with additional carriers being generated. As the avalanche multiplication is a self-sustaining process, a current signal may be produced and can be easily detected by readout circuitry associated with the SPAD. The avalanche breakdown process needs to be stopped (quenched) in order to detect a new photon by lowering the voltage bias across the diode below its breakdown point. In LIDAR devices, the SPAD pixels may be used to measure photon time-of-flight (ToF) from a synchronized light source to a scene object point and back to the sensor, which can be used to obtain a 3-dimensional image of the scene (as an example).

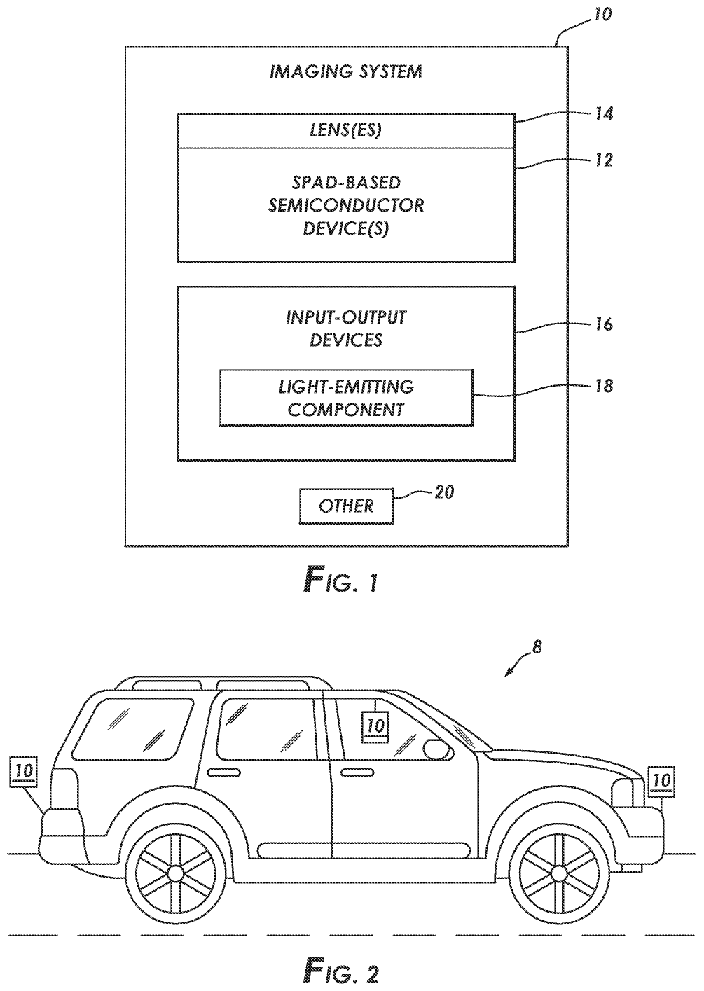

FIG. 1 is a functional block diagram of an illustrative imaging system such as imaging system 10. Imaging system 10 of FIG. 1 may be a vehicle safety system (e.g., an active braking system or other vehicle safety system), a surveillance system, a medical imaging system, a general machine vision system, or any other desired type of system.

Imaging system 10 may include or implement a LIDAR-based device (sometimes referred to as a LIDAR module) having SPAD device(s). The LIDAR module may use the SPAD device(s) to capture images of a scene and measure distances to obstacles (also referred to as targets) in the scene. As an example, in a vehicle safety system, information from the LIDAR module may be used by the vehicle safety system to determine environmental conditions surrounding the vehicle. As examples, vehicle safety systems may include systems such as a parking assistance system, an automatic or semi-automatic cruise control system, an auto-braking system, a collision avoidance system, a lane keeping system (sometimes referred to as a lane-drift avoidance system), a pedestrian detection system, etc. In at least some instances, the LIDAR module may form part of a semi-autonomous or autonomous self-driving vehicle.

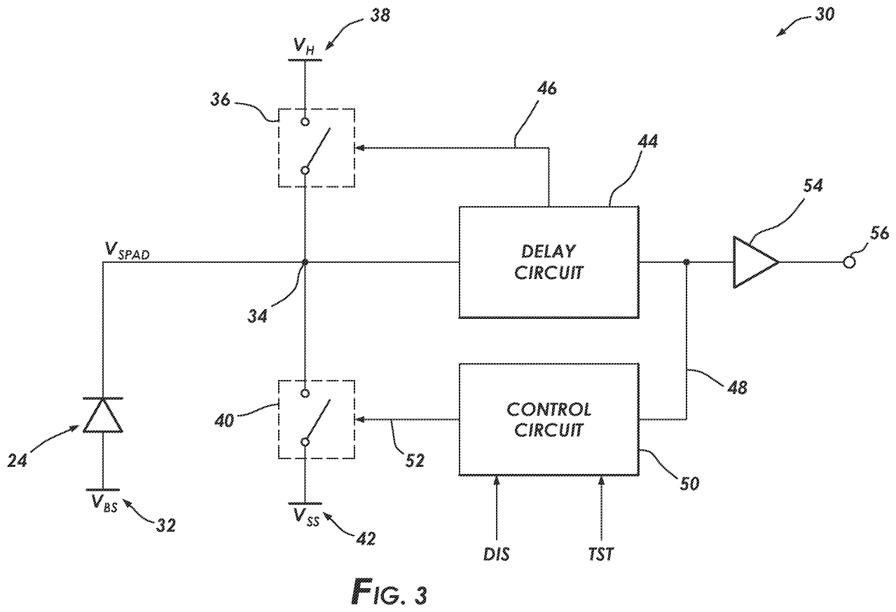

An illustrative example of a vehicle such as an automobile 8 is shown in FIG. 2. As shown in the illustrative example of FIG. 2, automobile 8 may include one or more SPAD-based imaging systems 10. The imaging systems may be vehicular safety systems as discussed above. In the illustrative example of FIG. 2, a first imaging system 10 is shown mounted on the front of car 8 (e.g., to capture images of the surroundings in front of the car), and a second imaging system 10 is shown mounted in the interior of car 8 (e.g., to capture images of the driver of the vehicle). If desired, an imaging system 10 may be mounted at the rear end of vehicle 8 (i.e., the end of the vehicle opposite the location at which first imaging system 10 is mounted in FIG. 2). The imaging system at the rear end of the vehicle may capture images of the surroundings behind the vehicle. These examples are merely illustrative. One or more imaging systems 10 may be mounted on or within a vehicle 8 at any desired location(s).

Referring back to FIG. 1, imaging system 10 may include one or more SPAD-based (semiconductor) devices 12. One or more lenses 14 may cover each SPAD-based device 12. During operation, lenses 14 (sometimes referred to as optics) may focus light onto corresponding SPAD-based semiconductor devices 12. SPAD-based devices 12 may each include (an array of) SPAD pixels that convert the light into digital data or analog signal in case of a SiPM. The SPAD-based device 12 may have any number of SPAD pixels (e.g., hundreds, thousands, millions, or more). In some SPAD-based devices, each SPAD pixel may be covered by a respective color filter element and/or microlens.

SPAD-based device 12 may include control circuitry. The control circuitry for SPAD-based device 12 may be formed either on-chip (e.g., on the same semiconductor substrate as the SPAD-based device 12) or off-chip (e.g., on a different semiconductor substrate as the SPAD-based device 12). The control circuitry may control operation of SPAD-based device 12. For example, the control circuitry may operate active quenching circuitry or other adjustable (transistor) circuitry within each SPAD pixel, may control one or more bias voltages provided to each SPAD pixel, may control/monitor the readout circuitry associated with each SPAD pixel, etc.

The SPAD-based semiconductor device 12 may optionally include additional circuitry such as logic gates, digital counters, time-to-digital converters, bias circuitry (e.g., source follower load circuits), sample and hold circuitry, amplifier circuitry, analog-to-digital (ADC) converter circuitry, data output circuitry, memory (e.g., buffer circuitry), address circuitry, etc. Any of the aforementioned circuits may form part of the control circuitry or, when provided on a per-pixel basis, may form part of the SPAD pixel.

If desired, 3D image data output from SPAD-based device 12 may be provided to downstream image processing circuitry. The image processing circuitry may process data gathered by the SPAD pixels to determine a depth map of the scene (as another example) using the time-of-flight data. The full 3D image data of the specific scene may be obtained by combining the depth map of the scene with an intensity map. The intensity map can refer to a spatial representation of photon intensity or photon count obtained from detected photons and can provide information on the spatial distribution of photon intensities/counts across a two-dimensional area or even a three-dimensional volume in certain applications. In some cases, some or all of the control circuitry for SPAD device 12 may be formed integrally with the image processing circuitry (e.g., on the same die or package).

Imaging system 10 may provide a user with numerous high-level functions. For example, a user may be provided with the ability to run user applications on system 10. To implement these functions, imaging system 10 may include input-output devices 16 such as keypads, buttons, input-output ports, joysticks, and displays. If desired, other functional modules and/or additional storage and processing circuitry (e.g., other components 20) may also be included in imaging system 10. Other such modules or circuitry may include volatile and nonvolatile memory (e.g., random-access memory, flash memory, hard drives, solid state drives, etc.), microprocessors, microcontrollers, digital signal processors, application specific integrated circuits, and/or other processing circuits for other (non-imaging) functional modules.

Input-output devices 16 may include output devices that work in combination with SPAD-based devices 12. For example, one or more light-emitting components 18 may be included in imaging system 10 to emit light (e.g., infrared light or light of any other desired type). Light-emitting component 18 may be a laser, light-emitting diode, or any other desired type of light-emitting component. SPAD-based device 12 may measure the reflection of the light off of an object to measure distance to the object in a LIDAR scheme (e.g., in scenarios where imaging system 10 implements or includes a LIDAR module). The control circuitry that is used to control operation of SPAD-based device 12 may optionally also be used to control operation of light-emitting component 18 for a coordinated sensing scheme.

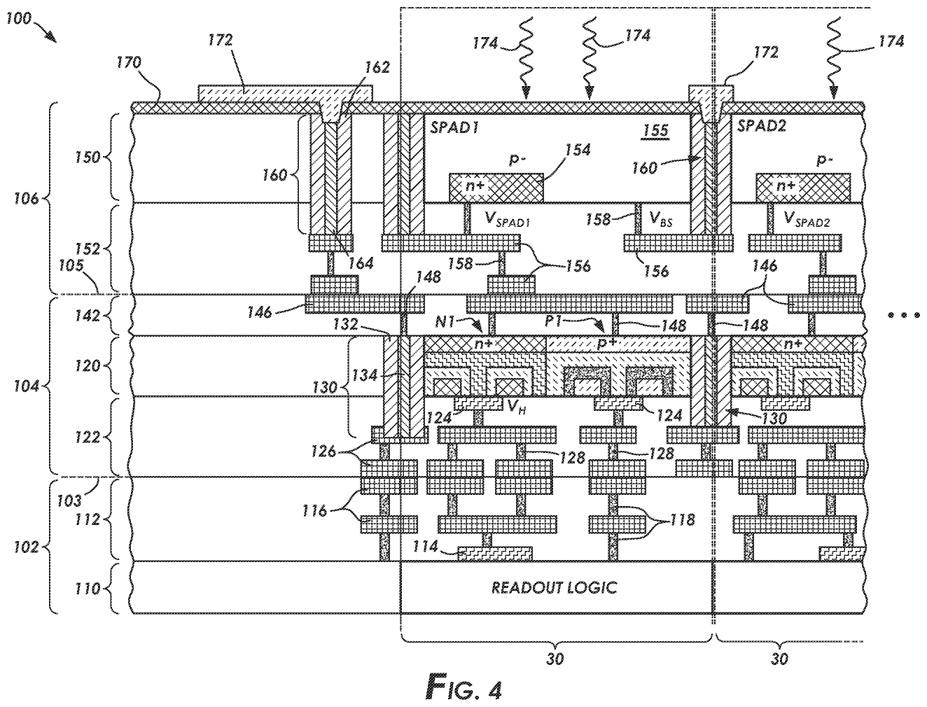

FIG. 3 is a schematic diagram of an illustrative SPAD pixel such as SPAD pixel 30. A plurality or an array of such a SPAD pixel may be formed in SPAD device 12 as shown in FIG. 1. As shown in FIG. 3, SPAD pixel 30 may include a SPAD 24 having an anode terminal connected to voltage supply terminal 32 and a cathode terminal 34 connected to power supply line 38 (e.g., a power supply terminal on which a high voltage V_{H} can be provided) via switch 36 (e.g., transistor 36) when switch 36 is turned on or activated. The anode terminal 32 may be biased to voltage VBS. To prepare for a detection operation using SPAD pixel 30, supply voltage terminals 32 and 38 may be used to bias SPAD 24 to a voltage (e.g., across SPAD 24) that is higher than the breakdown voltage of SPAD 24. The breakdown voltage can be defined as the reverse bias voltage that can be applied across SPAD 24 without causing an exponential increase in the reverse forward current in SPAD 24. When SPAD 24 is reverse biased above the breakdown voltage in this manner, absorption of a single photon can trigger a short-duration but relatively large avalanche current through impact ionization, thereby providing single-photon sensitivity.

A quenching circuit may be used to lower the bias voltage of SPAD 24 below or at the level of the breakdown voltage. Lowering the bias voltage of SPAD 24 below the breakdown voltage stops the avalanche process and the corresponding avalanche current. There are numerous ways to form a quenching circuit. As examples, the quenching circuit may be a passive quenching circuit or an active quenching circuit. A passive quenching circuit may, without external control or monitoring, automatically quench the avalanche current once initiated. As an example, a resistor (e.g., a passive resistive component) coupled between the cathode terminal of the SPAD and a corresponding voltage supply terminal may serve as a passive quenching circuit. On the other hand, an active quenching circuit may require external control or monitoring to apply a voltage to the cathode terminal of the SPAD.

In the example of FIG. 3, pixel 30 includes an active quenching circuit. The active quenching circuit may reduce the time it takes for SPAD 24 to be quenched and reset (e.g., the dead-time). This reduction of the dead-time may allow SPAD 24 to detect incident light at a faster rate than when a passive quenching circuit is used, thereby improving the counting rate of the SPAD device. As shown in FIG. 3, the (active) quenching circuit of pixel 30 may include switch 40 (e.g., transistor 40) coupling cathode terminal 34 to a ground power supply line 42 (e.g., a ground line on which ground voltage V_{SS} can be provided). When turned on, switch 40 may provide the ground voltage V_{SS} at terminal 42 to cathode terminal 34 of SPAD 24. Switch 40 configured in this way is sometimes referred to as a pull-down transistor or a disabling transistor.

To control the state of switch 40, the quenching circuit of pixel 30 may also include control circuit 50 that supplies a control signal along path 52 that controls the state of switch 40. For example, the control circuit 50 may assert or de-assert the control signal to switch between on and off states of the switch 40 or may otherwise control switch 40 in any suitable manner. In the example of FIG. 3, the output signal from delay circuit 44 coupled along the SPAD readout path (e.g., the signal along path 48) may be used to generate a control signal on path 52. In other words, in this active quenching scheme, the active quenching circuit may modulate the SPAD quench resistance based on SPAD operation. For example, before a photon is detected, quench resistance is set high, and then once a photon is detected, the quench resistance is minimized so that the avalanche is quenched to reduce recovery time. In the example of FIG. 3, control circuit 50 may control switch 40 to be in an open or high resistivity state to set the SPAD quench resistance to high before a photon is detected, and may control switch 40 to be in a closed or low resistivity state once a photon is detected to quench the avalanche.

In a similar manner, delay circuit 44 may provide a control signal on path 46 (e.g., based on an introduced delay) to control switch 36 to be in open or closed states at corresponding times. As an example, a suitable time period after the quenching operation of SPAD 24 (e.g., the assertion of the control signal on path 52 to close switch 40), delay circuit 44 may provide an asserted control signal to close switch 36 to reset or recharge SPAD 24 and prepare for detection of a subsequent photon. The time period after the quenching operation and the reset/recharge operation of SPAD 24 can have a duration equal to tens or hundreds of nanoseconds (ns), less than 100 ns, less than 10 ns, less than 1 ns, or more than 1 microsecond. Switch 36 is therefore sometimes referred to as a pull-up transistor or recharge transistor.

In the example of FIG. 3, the readout path of pixel 30 may include delay circuit 44 and driver circuit 54. Delay circuit 44 and driver circuit 54 may pass a detection signal responsive to a detected impinging photon from cathode terminal 34 to a pixel output terminal 56. If desired, specific functional circuits may be coupled along the readout path of pixel 30 between terminals 34 and 56 instead of or in addition to delay circuit 44 and/or driver circuit 54. For example, such functional circuits may include a variable or constant hold-off timer circuit, a variable or constant reset timer circuit, and/or a reset time-out circuit, among others. The detection signal exiting pixel 30 from output terminal 56 may be processed by downstream digital processing circuitry.

To provide additional functionalities to SPAD pixel 30, control circuit 50 may receive additional input signals, such as DIS and TST. In particular, input signal DIS may be a disable signal that, when asserted, enables control circuit 50 to use (assert) the control signal on path 52 to maintain switch 40 in a closed or activated state such that SPAD avalanching is prevented, thereby actively disabling pixel 30 from performing sensing operations. Input signal TST may be a test signal that, when asserted, enables control circuit 50 to control switch 40 and/or other pixel elements to respond to a test input, thereby providing testability to pixel 30.

Delay circuit 44, control circuit 50, driver 54, and/or any other circuitry associated with the readout of a SPAD pixel 30 can be referred to collectively and defined herein as “digital readout logic.” For example, the other circuitry which may include one or more comparator, one or more pulse generators, one or more level shifter, one or more inverter, etc. The digital readout logic can be powered by a power supply voltage that is lower than supply voltage V_{H}, sometimes referred to as a low supply voltage. As an example, the low supply voltage for powering the digital readout logic can be equal to 1.8 V. 1-2 V_{SS}, 2-3 V. 3.3 V. 3-4 V, or other voltage lower than V_{H}.

On the other hand, switches 36 and 40 that are powered using high voltage V_{H} are sometimes referred to and defined herein as “high voltage” transistors or analog high voltage (HV) devices. High voltage transistors 36 and 40 coupled to cathode terminal 34 are considered analog devices since the signal generated at cathode terminal 34 when SPAD 24 senses an impinging photon is an analog signal. As an example, the high voltage V_{H} for powering the analog high voltage transistors 36 and 40 can be equal to 5 V, 6 V, 7 V, 5-7 V, 4-6 V, 6-8 V, 4-8 V, more than 8 V, or other voltage greater than the low voltage powering the digital readout logic. On the other hand, bias voltage VBS at the anode terminal 32 can be set equal to at least 17 V, 18 V. 19 V, 20 V, 17-20 V, more than 10 V, more than 12 V, more than 14 V, more than 16 V, or other suitable level to ensure that SPAD 24 is biased in the breakdown operating regime.

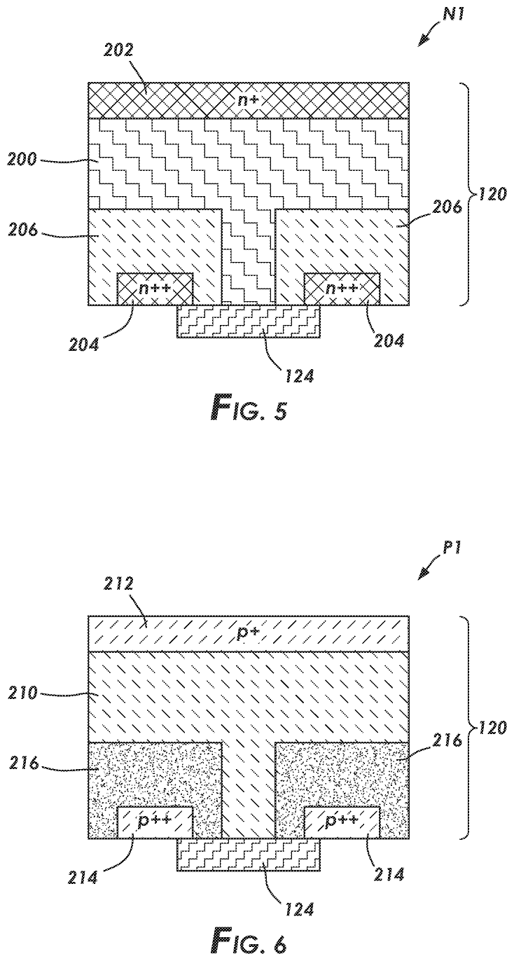

In accordance with some embodiments, the SPAD pixel circuitry can be implemented using a stacked die arrangement, sometimes referred to as 3-dimensional (3D) stacking. The stacked die arrangement may include two or more die with different components and circuitry that, when stacked vertically together, form the SPAD pixel circuitry. FIG. 4 is a cross-sectional side view of an example SPAD circuitry 100 implemented using a first die such as die 102, a second die such as die 104, and a third die such as die 106 stacked vertically with respect to one another. Die 106 may include only the SPADs (e.g., an array of SPADs) and is sometimes referred to and defined herein as a sensor die 106. Sensor die 106 may be configured as a backside illuminated (BSI) sensor die. Die 104 may include the analog high voltage (HV) transistors that are powered using high voltage V_{H} and is therefore sometimes referred to and defined herein as an analog high voltage die or an analog die 104. The backside illuminated sensor die 106 can be stacked on a back side of analog high voltage die 104, as shown in FIG. 4. Die 102 may include the digital readout logic that is powered using a lower supply voltage that is less than V_{H} and is therefore sometimes referred to and defined herein as a digital readout logic (low voltage) die or a digital die 102. Analog high voltage die 104 may be stacked on the front side of the digital readout logic die 102, as shown in FIG. 4. In other words, the analog high voltage die 104 may be interposed or sandwiched between BSI sensor die 106 and digital readout logic (low voltage) die 102.

As shown in FIG. 4, digital readout logic die 102 may include a semiconductor substrate such as a silicon substrate 110. The digital readout logic, which can include delay circuit 44 (see FIG. 3), control circuit 50, driver 54, and/or any other circuitry associated with the readout of each SPAD pixel 30 can be formed in or on semiconductor substrate 110. The digital readout logic can have one or more gate conductors such as exemplary gate conductor 114 formed over semiconductor substrate 110.

An interconnect stack such as interconnect stack 112 can be formed on semiconductor substrate 110. Interconnect stack 112 may include alternating routing layers and via layers. If desired, interconnect stack 112 can optionally include only one routing layer and only one via layer. Each routing layer can include conductive (metal) routing paths such as metal routing structures 116 formed in a layer of dielectric material. Each via layer can include conductive (metal) vias such as metal via structures 118 formed in a layer of dielectric material. Interconnect stack 112 is therefore sometimes referred to as a dielectric stack (e.g., an interconnect stack having conductive routing paths formed within dielectric material such as silicon dioxide). The conductive routing structures 116 and the conductive via structures 118 can be formed using copper, aluminum, tungsten, titanium, gold, silver, nickel, a metal alloy, a combination of metals, and/or other types of conductive material. The metal routing structures 116 and the metal via structures 118 can form an electrical network for interconnecting together various components within die 102 and for coupling the digital readout logic on die 102 to other off-chip components (e.g., to components on die 104, die 106, and/or other external components).

Analog high voltage die 104 may be stacked on digital readout logic die 102. Analog high voltage die 104 may include a semiconductor substrate such as a silicon substrate 120. High voltage devices, such as n-type transistor N1 and p-type transistor P1, can be formed in semiconductor substrate 120. N-type transistor N1 may represent the high voltage pull-down switch 40 in FIG. 3, whereas p-type transistor P1 may represent the high voltage pull-up transistor 36 in FIG. 3. As shown in FIG. 4, each SPAD pixel 30 may include an HV n-type transistor N1 and a HV p-type transistor P1. This is exemplary. As another example, SPAD pixel 30 might include only one HV n-type transistor without any p-type transistor. As another example, SPAD pixel 30 might include only one HV p-type transistor without any n-type transistor. As another example, SPAD pixel 30 might include one or more HV n-type transistors. As another example, SPAD pixel 30 might include one or more HV p-type transistors. As another example, SPAD pixel 30 might include one or HV n-type transistor(s) and one or more HV p-type transistor(s).

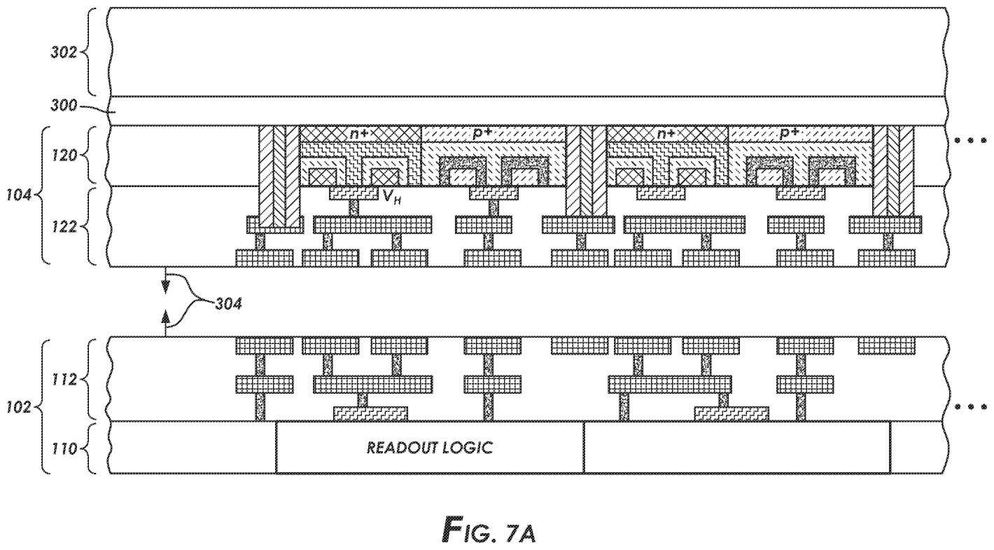

A more detailed view of the n-type high voltage (HV) transistor N1 is shown in FIG. 5. As shown in FIG. 5, transistor N1 can include an n-type drift region 200, an n+ layer 202 formed on the back side of n-type drift region 200, and n++ contacts 204 formed in respective p-body (implant) regions 206 at the front side of n-type drift region 200. The n+ layer 202 may be configured as a drain terminal of transistor N1, whereas the n++ contacts 204 may be configured collectively as a source terminal of transistor N1. N-type transistor N1 having source and drain terminals formed at or near opposing sides or surfaces of substrate 120 in this way is sometimes referred to and defined herein as a “vertical transistor.” The terms “source” and “drain” are sometimes used interchangeably when referring to current-conducting terminals of a transistor. The source and drain terminals are therefore sometimes referred to as “source-drain” terminals (e.g., the source terminal can be referred to as a first source-drain terminal, whereas the drain terminal can be referred to as a second source-drain terminal, or vice versa). Transistor N1 can have a gate conductor 124 formed on a side of semiconductor substrate 120 and connecting the source terminals 204. The side of substrate 120 at/on which gate conductor 124 is formed is typically referred to as the “front side” of the substrate or die.

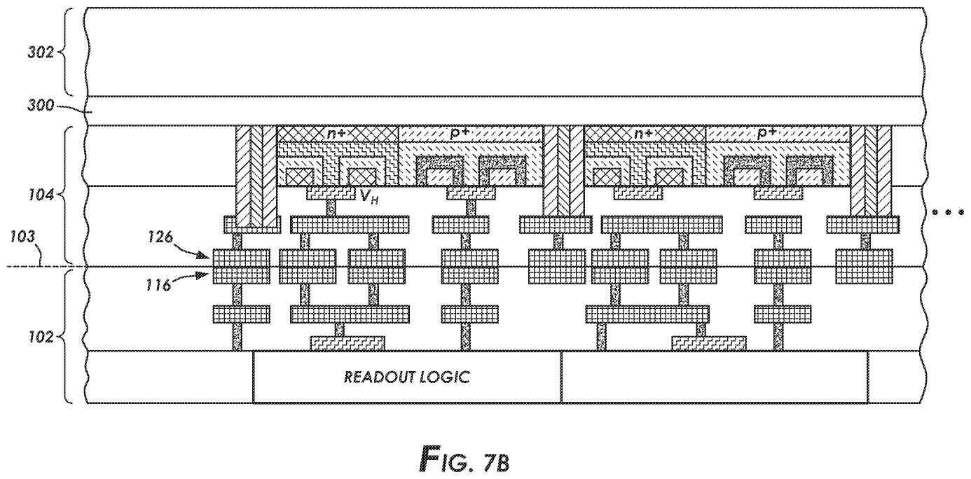

A more detailed view of the p-type high voltage (HV) transistor P1 is shown in FIG. 6. As shown in FIG. 6, transistor P1 can include an p-type substrate region 210, an p+ layer 212 formed on the back side of p-type substrate region 210, and p++ contacts 214 formed in respective n-body (implant) regions 216 at the front side of p-type substrate region 210. The p+ layer 212 may be configured as a drain terminal of transistor P1, whereas the p++ contacts 214 may be configured collectively as a source terminal of transistor P1. P-type transistor P1 having source and drain terminals formed at or near opposing sides or surfaces of substrate 120 in this way is sometimes referred to and defined herein as a “vertical transistor.” The terms “source” and “drain” are sometimes used interchangeably when referring to current-conducting terminals of a transistor and are therefore sometimes referred to as “source-drain” terminals. Transistor P1 can have a gate conductor 124 formed on the front side of semiconductor substrate 120 and connecting the source terminals 214.

Referring back to FIG. 4, an interconnect stack such as interconnect stack 122 can be formed on the front side (surface) of semiconductor substrate 120. Interconnect stack 122 may include alternating routing layers and via layers. Each routing layer in interconnect stack 122 can include conductive (metal) routing paths such as metal routing structures 126 formed in a layer of dielectric material. Each via layer in interconnect stack 122 can include conductive (metal) vias such as metal via structures 128 formed in a layer of dielectric material. Interconnect stack 122 is therefore sometimes referred to as a dielectric stack (e.g., an interconnect stack having conductive routing paths formed within dielectric material such as silicon dioxide). The conductive routing structures 126 and the conductive via structures 128 can be formed using copper, aluminum, tungsten, titanium, gold, silver, nickel, a metal alloy, a combination of metals, and/or other types of conductive material. The metal routing structures 126 and the metal via structures 128 can form an electrical network for interconnecting together various components within die 104 and for coupling the high voltage devices (e.g., transistors N1 and P1) to the digital readout logic in die 102.

Interconnect stack 122 of die 104 may be bonded to interconnect stack 112 at a wafer bonding interface 103. Bonding interface 103 can be formed to ensure that the dielectric material in the interconnect stacks 112 and 122 are properly attached and also to ensure that the conductive routing structures 116 and 126 at bonding interface 103 are properly connected (bonded). Such bonding at interface 103 that ensures both a physical coupling and electrical coupling is sometimes referred to herein as a hybrid bond.

Interconnect stack 122 formed on the front side of semiconductor substrate 120 is illustrative. Furthermore, an interconnect stack such as interconnect stack 142 can be formed on the back side (surface) of semiconductor substrate 120. Interconnect stack 142 may include alternating routing layers and via layers. Each routing layer in interconnect stack 142 can include conductive (metal) routing paths such as metal routing structures 146 formed in a layer of dielectric material. Each via layer in interconnect stack 142 can include conductive (metal) vias such as metal via structures 148 formed in a layer of dielectric material. Interconnect stack 142 is therefore sometimes referred to as a dielectric stack (e.g., an interconnect stack having conductive routing paths formed within dielectric material such as silicon dioxide). The conductive routing structures 146 and the conductive via structures 148 can be formed using copper, aluminum, tungsten, titanium, gold, silver, nickel, a metal alloy, a combination of metals, and/or other types of conductive material. The metal routing structures 146 and the metal via structures 148 can form an electrical network for interconnecting together various components within die 104 and for coupling the high voltage devices (e.g., transistors N1 and P1) to the SPADs in sensor die 106.

One or more through silicon via (TSV) structures such as TSV 130 can be formed within analog high voltage die 104. In the example of FIG. 4, TSV structure 130 can extend through the entire depth of semiconductor substrate 120 (e.g., from the back side of substrate 120 to at least the front side of substrate 120). In some implementations, TSV structure 130 can extend at least partially into the frontside interconnect stack 122 and make an electrical connection with one of the metal routing structures 126 or with a conductive via. If desired, TSV structure 130 can additionally or alternatively extend at least partially into the backside interconnect stack 142. TSV structure 130 can make an electrical connection with metal routing structures 146 in the backside interconnect stack 142 either directly or using a conductive via 148 as shown in FIG. 4. The TSV structure 130 can be lined with an insulating layer 132 and filled with conductive material 134. The insulating layer 132 can be formed from silicon dioxide, silicon nitride, silicon oxynitride, or other insulating material. The filler material 134 can be formed from tungsten, aluminum, copper, copper tungsten, titanium, tantalum, a combination of these materials, or other conductive materials suitable for via structures.

Sensor die 106 may be stacked on the back side of the analog high voltage die 104. Sensor die 106 may include a semiconductor substrate such as a silicon substrate 150. An array of SPADs can be formed in semiconductor substrate 150. Each SPAD pixel 30 may include a respective SPAD (see, e.g., SPAD1 and an adjacent SPAD2, etc.). Each SPAD may include an n+ contact 154 formed in a p-type region 155 (e.g., a p-substrate). The n+ contact 154 may serve as the cathode terminal on which a SPAD output voltage is generated, whereas the p-type region 155 may serve as the anode terminal configured to receive bias voltage VBS. In the example of FIG. 4, a first SPAD1 can be configured to output a corresponding voltage VSPAD1 while a second (neighboring) SPAD2 can be configured to output a corresponding voltage VSPAD2. The output voltage of each SPAD may be provided to downstream image processing circuitry such as to digital readout logic on die 102 or to other image processing circuitry in imaging system 10 of FIG. 1. The image processing circuitry may process data gathered by the SPAD pixels to determine a depth map of the scene using time-of-flight data. The depth map may be combined with an intensity map to obtain a full 3D image of a physical scene or environment.

An interconnect stack such as interconnect stack 152 can be formed on a front side (surface) of semiconductor substrate 150. Interconnect stack 152 may include alternating routing layers and via layers. Each routing layer in interconnect stack 152 can include conductive (metal) routing paths such as metal routing structures 156 formed in a layer of dielectric material. Each via layer in interconnect stack 152 can include conductive (metal) vias such as metal via structures 158 formed in a layer of dielectric material. Interconnect stack 152 is therefore sometimes referred to as a dielectric stack (e.g., an interconnect stack having conductive routing paths formed within dielectric material such as silicon dioxide). The conductive routing structures 156 and the conductive via structures 158 can be formed using copper, aluminum, tungsten, titanium, gold, silver, nickel, a metal alloy, a combination of metals, and/or other types of conductive material. The metal routing structures 156 and the metal via structures 158 can form an electrical network for interconnecting together various components within die 106 and for coupling the array of SPADs to the analog high voltage die 104. The metal routing structures 156 can be coupled to the SPAD cathode terminals (e.g., for reading out the SPAD output voltages) and can be coupled to the SPAD anode terminals (e.g., for providing voltage VBS to bias each SPAD component in the breakdown operating regime).

Interconnect stack 152 of die 104 may be bonded to interconnect stack 142 at a wafer bonding interface 105. Bonding interface 105 can be formed to ensure that the dielectric material in the interconnect stacks 142 and 152 are properly attached and also to ensure that the conductive routing structures 146 and 156 at bonding interface 105 are properly connected (bonded). Such bonding at interface 105 that ensures both a physical coupling and electrical coupling is sometimes referred to herein as a hybrid bond.

One or more through silicon via (TSV) structures such as TSV 160 can be formed within sensor die 106. In some embodiments, TSV structure 160 can extend through the entire depth of semiconductor substrate 150 (e.g., through silicon via 160 can extend from the back side of substrate 150 to at least the front side of substrate 150). TSV structure 160 can extend at least partially into interconnect stack 152 and make an electrical connection with one of the metal routing structures 156 or with a conductive via. If desired, an additional interconnect stack can be formed between substrate layer 150 and passivation layer 170 in wafer 106, and TSV structure 160 can additionally or alternatively extend at least partially into or extend entirely through this additional interconnect stack. The TSV structure 160 can be lined with an insulating layer 162 and filled with conductive material 164. The insulating layer 162 can be formed from silicon dioxide, silicon nitride, silicon oxynitride, or other insulating material. The conductive filler material 164 can be formed from tungsten, aluminum, copper, copper tungsten, titanium, tantalum, a combination of these materials, or other conductive materials suitable for via structures.

A passivation layer such as passivation layer 170 may be formed along the back side (surface) of substrate 150. Passivation layer 170 may be formed using silicon dioxide, silicon nitride, silicon oxynitride, polyimide, other polymers, or other passivation material. Contact pads such as contact pads 172 (e.g., wire bond pads or other types of metal pads) can be formed on passivation layer 170. Contact pads 172 can be coupled to the through silicon vias 160 that traverse substrate layer 150 of sensor die 106. During operation of SPAD circuitry 100, incoming light 174 can enter through the back surface of sensor die 106 (i.e., the back side of sensor die substrate 150). Operated in this way, SPAD circuitry 100 can be referred to as a backside illuminated (BSI) SPAD-based sensor.

An image system as described herein may have a SPAD pixel vertically stacked with HV devices and corresponding readout logic. A SPAD may be connected to HV devices through an interconnect stack comprising TSVs and conductive vias. The HV devices may further be connected to external contact pads using another such interconnect stack. In some implementations, the HV devices are vertically stacked with the corresponding readout logic for the SPAD through another interconnect stack, and the readout logic is then connected to external contact pads through yet another interconnect stack. Arranged in the way shown in FIG. 4 where the HV devices are stacked vertically with respect to the SPAD pixels and where the readout logic on wafer 102 is coupled to external contact pads using TSVs 130 traversing substrate layer 120 in wafer 104 and using TSVs 160 traversing substrate layer 150 in wafer 106, the vertically stacked SPAD circuitry 100 is technically advantageous and beneficial by providing active in-pixel quenching, a smaller overall form factor, and improved reliability due to reduced need for wire bonding between the stacked dies. For example, compared to non-stacked configurations in which the SPAD pixels and the HV devices are formed in the same wafer, the vertically stacked SPAD circuitry can help reduce the overall footprint of the package by at least 30% or more, at least 40% or more, or at least 50% or more.

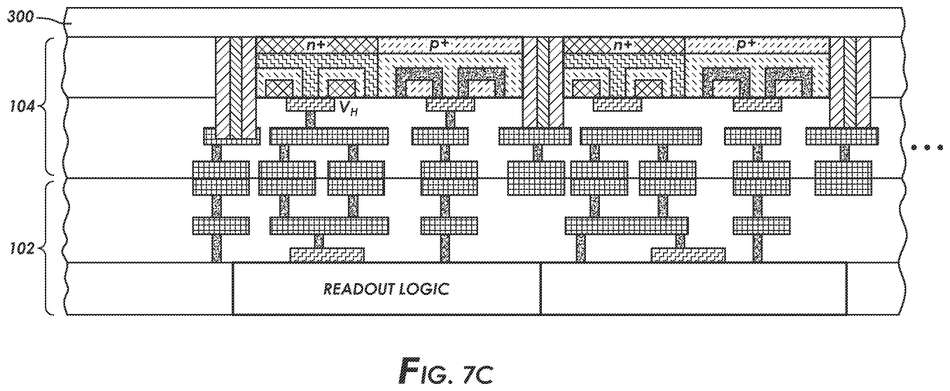

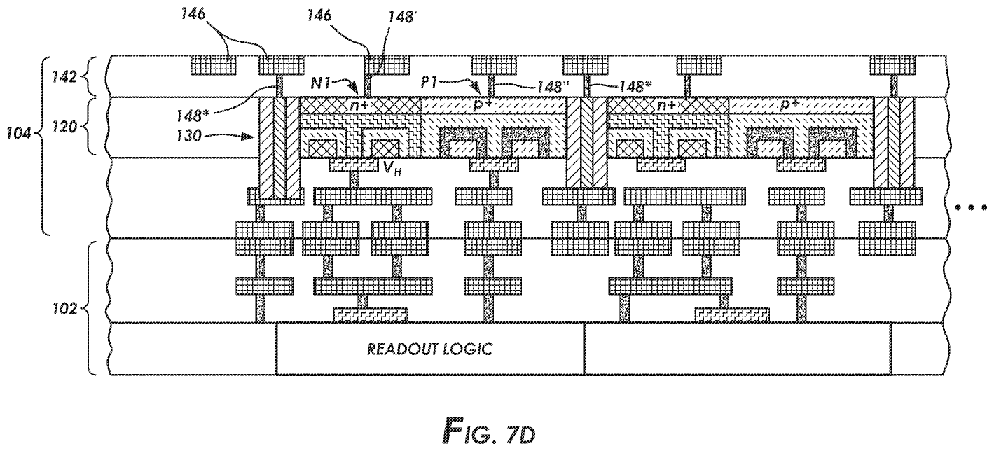

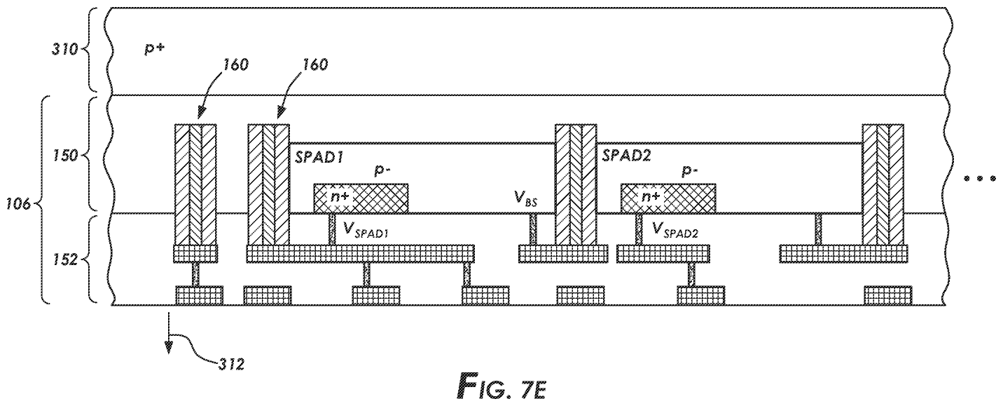

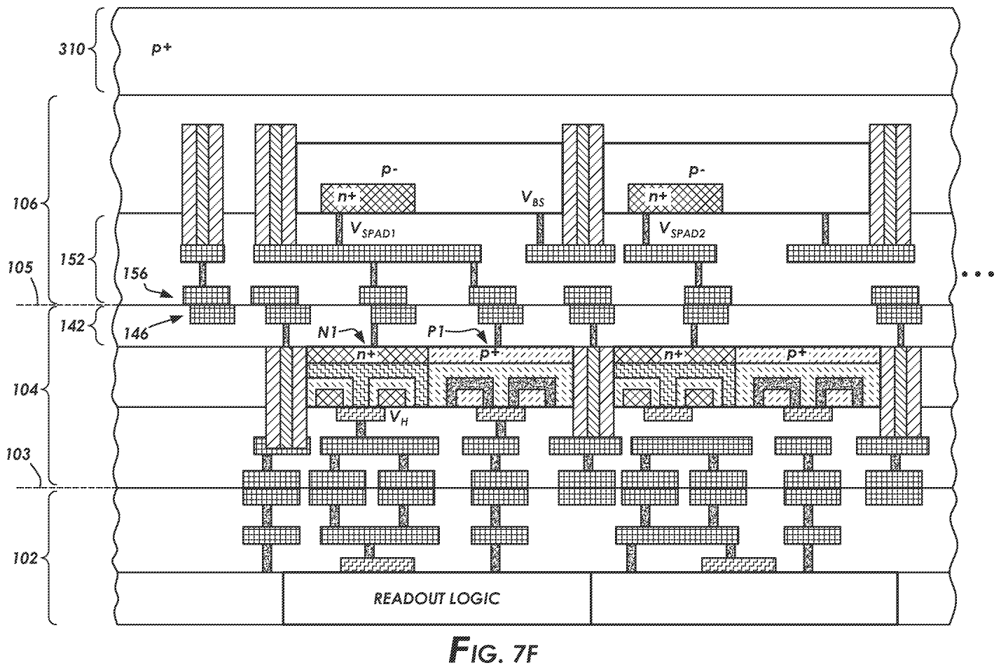

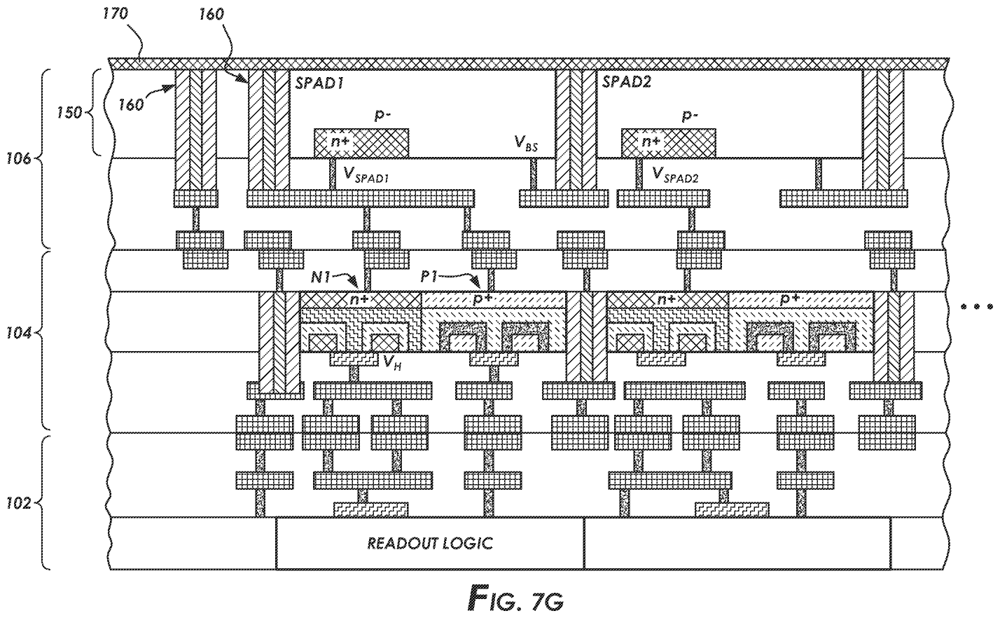

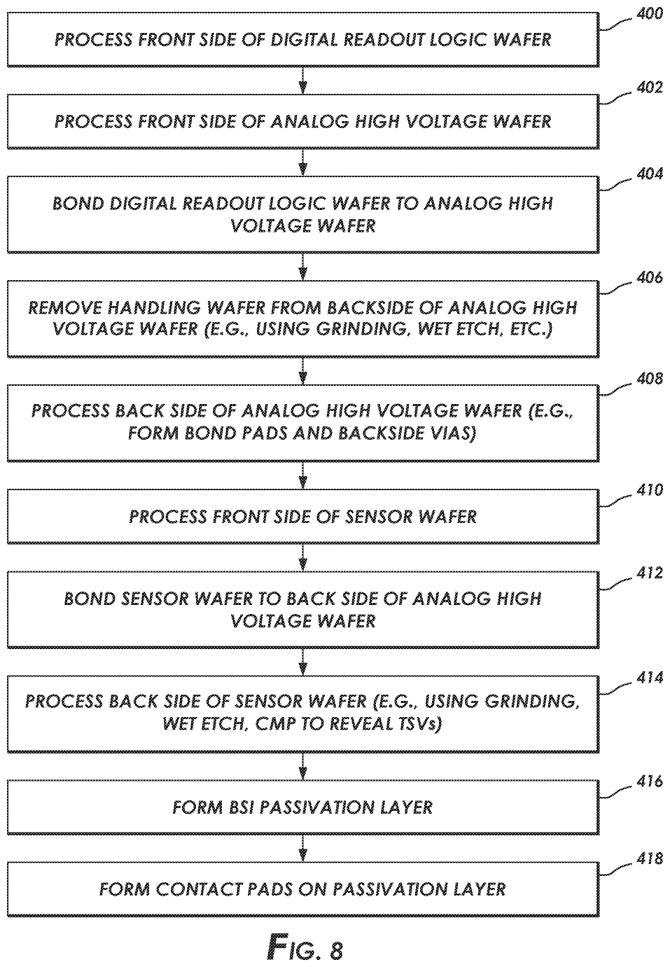

The process of fabricating SPAD circuitry 100 of FIG. 4 can be illustrated in the series of snapshots shown in FIGS. 7A-7G. FIG. 7A is a cross-sectional side view showing frontside processing for digital readout logic wafer 102 and analog high voltage wafer 104. As shown in FIG. 7A, interconnect stack 112 can be formed on the front side (surface) of semiconductor substrate 110. Digital readout logic wafer 102 is sometimes referred to as digital readout logic layers and can later be separated or diced into a plurality of digital readout logic dies 102. On the other hand, interconnect stack 122 can be formed on the front side (surface) of semiconductor substrate 120 for wafer 104. Analog HV wafer 104 is sometimes referred to as analog high voltage layers and can later be separated or cut into a plurality of analog high voltage dies 104. Prior to the frontside processing of wafer 104, semiconductor substrate 120 may be attached to an oxide layer such as buried oxide (BOX) layer 300. Buried oxide layer 300 can be formed from silicon dioxide, aluminum oxide, zinc oxide, indium tin oxide, titanium oxide, or gallium oxide (as examples). The buried oxide layer 300 can be formed on a handling wafer such as carrier wafer 302. The stacking of semiconductor substrate 120 on buried oxide layer 300 and carrier wafer 302 is sometimes referred to as a silicon-on-insulator (SOI) configuration. The front surface of wafer 102 can be brought against the front surface of wafer 104 in preparation for the next bonding process of FIG. 7B, as indicated by arrows 304.

FIG. 7B is a cross-sectional side view showing wafer bonding between digital readout logic wafer 102 and analog high voltage wafer 104. As shown in FIG. 7B, wafers 102 and 104 can be bonded at interface 103. Bonding interface 103 can be formed to ensure that the dielectric material in the interconnect stacks 112 and 122 are properly attached and also to ensure that the conductive routing structures 116 and 126 at bonding interface 103 are electrically connected (bonded). Such bonding at interface 103 that ensures both physical coupling and electrical coupling is sometimes referred to herein as a hybrid bond.

FIG. 7C is a cross-sectional side view showing removal of carrier wafer 302 from the back side of analog high voltage wafer 104. The removal of carrier (handling) wafer 302 can be accomplished via a mechanical grinding process and/or a wet etch process and chemical-mechanical polishing (CMP). The wet etch process can involve using an etchant that can selectively remove carrier wafer 302 while stopping at the buried oxide layer 300 (e.g., the wet etchant will only minimally remove silicon dioxide).

FIG. 7D is a cross-sectional side view showing additional backside processing for analog high voltage wafer 104. As shown in FIG. 7D, interconnect stack 142 can be formed on the back side (surface) of semiconductor substrate 120. Interconnect stack 142 may be formed from the buried oxide layer 300. The metal routing structures 146 in interconnect stack 142 can be coupled to one or more TSV structures 130 (e.g., using via 148*), to the drain terminals of one or more high voltage devices N1 (e.g., using via 148′), and to the drain terminals of one or more high voltage devices P1 (e.g., using via 148″). This example in which interconnect stack 142 is formed from the buried oxide layer 300 is illustrative. In other embodiments, interconnect stack 142 can be separately formed on the backside of substrate 120 without first forming the buried oxide layer 300.

FIG. 7E is a cross-sectional side view showing frontside processing for sensor wafer 106. As shown in FIG. 7E, interconnect stack 152 can be formed on the front side (surface) of semiconductor substrate 150. Sensor wafer 106 is sometimes referred to as sensor or SPAD layers and can later be separated or diced into a plurality of sensor dies 106. Prior to the frontside processing of wafer 106, semiconductor substrate 150 may be attached to p+ silicon layer 310. Substrate layer 150 may be an epitaxial silicon layer. TSV structures 160 can be formed at least partially through epitaxial silicon layer 150 and interconnect stack 152. The front surface of wafer 106 can be brought against the back surface of wafer 104 in preparation for the next bonding process of FIG. 7F, as indicated by arrow 312.

FIG. 7F is a cross-sectional side view showing wafer bonding between sensor wafer 106 and the processed back side of analog high voltage wafer 104. As shown in FIG. 7F, wafers 106 and 104 can be bonded at interface 105. Bonding interface 105 can be formed to ensure that the dielectric material in the interconnect stacks 152 and 142 are properly attached and also to ensure that the conductive routing structures 156 and 146 at bonding interface 105 are electrically connected (bonded). Such bonding at interface 105 that ensures both physical coupling and electrical coupling is sometimes referred to herein as a hybrid bond.

FIG. 7G is a cross-sectional side view showing additional backside processing for sensor wafer 106. As shown in FIG. 7G, the p+ silicon layer 310 of FIG. 7F can be removed via a mechanical grinding and/or a wet etch process. Thereafter, a planarizing process such as a chemical mechanical polishing (CMP) process can be used to polish down the back side of substrate layer 150 to reveal the TSV structures 160 (e.g., so that the TSVs 160 are exposed at the back side of substrate layer 150). After the CMP or other planarization process, passivation layer 170 can be formed on the back surface of substrate layer 150. Passivation layer 170 may be formed using silicon dioxide, silicon nitride, silicon oxynitride, polyimide, other polymers, or other passivation material. Additional processing steps can then occur to selectively pattern passivation layer 170 and to form contact pads 172 that are coupled to one or more TSV structures 160 (see, e.g., the completed die stack of FIG. 4).

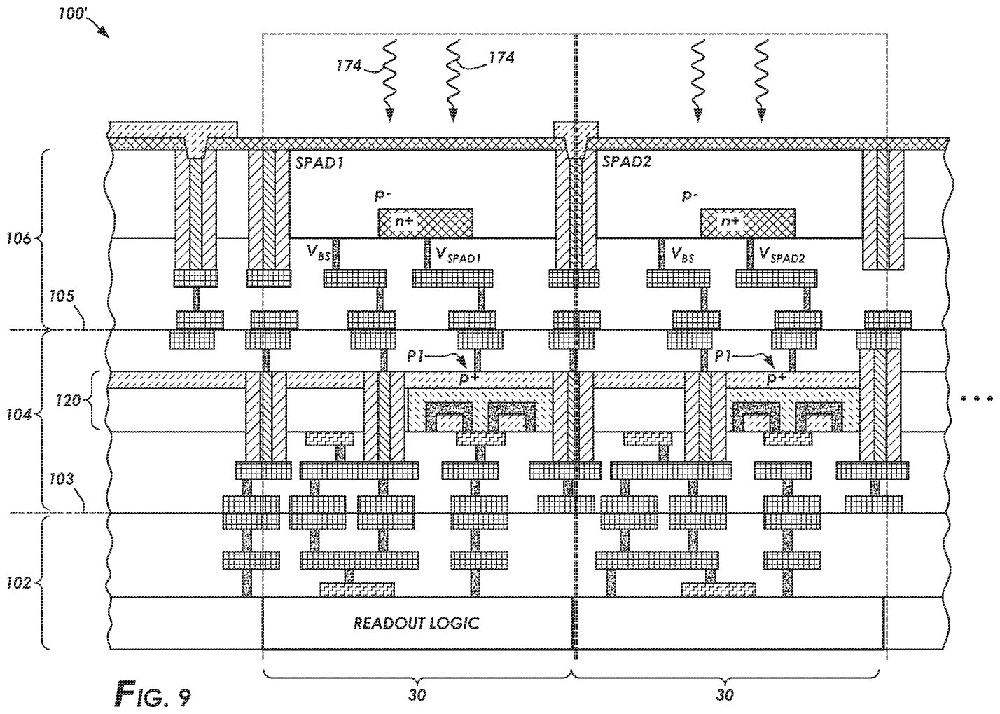

FIG. 8 is a flow chart of illustrative steps for fabricating the SPAD circuitry of the type shown in FIGS. 4-7. During the operations of block 400, the front side of digital readout logic wafer 102 can be processed. For example, the digital readout logic circuits can be formed in the front side of semiconductor substrate 110, and interconnect 112 can be formed on the front side of semiconductor substrate 110. During the operations of block 402, the front side of analog high voltage wafer 104 can be processed. For example, the high voltage switches N1 and P1 can be formed in the front side of semiconductor substrate 120, and interconnect 122 can be formed on the front side of semiconductor substrate 120. The result of blocks 400 and 402 can be shown in FIG. 7A. Although the operations of block 402 are shown to occur after the operations of block 400, block 402 can alternatively occur before or in parallel (simultaneously) with block 400.

During the operations of block 404, digital readout logic wafer 102 can be bonded to analog high voltage wafer 104. The result of block 404 can be shown in FIG. 7B, where wafers 102 and 104 are attached at hybrid bonding interface 103.

During the operations of block 406, the handling wafer 302 can be removed from the backside of analog high voltage wafer 104. For example, handling (carrier) wafer 302 can be removed using a mechanical grinding and/or a wet etch process. The wet etch process can involve using an etchant that can selectively remove carrier wafer 302 while stopping at the buried oxide layer 300 (e.g., the wet etchant will only minimally remove silicon dioxide). The result of block 406 can be shown in FIG. 7C.

During the operations of block 408, the back side of analog high voltage wafer 104 can be processed. For example, interconnect stack 142 can be formed on the back side (surface) of semiconductor substrate 120 (see, e.g., FIG. 7D). Interconnect stack 142 may be formed from the buried oxide layer 300. The metal routing structures 146 in interconnect stack 142 can be coupled to one or more TSV structures 130 (e.g., using via 148*), to the drain terminals of one or more high voltage devices N1 (e.g., using via 148′), and to the drain terminals of one or more high voltage devices P1 (e.g., using via 148″). Vias 148*, 148′, and 148″ can be referred to as backside vias. The metal routing structures 146 exposed at the surface of interconnect stack 142 are sometimes referred to as backside bond pads.

During the operations of block 410, the front side of sensor wafer 106 can be processed. For example, interconnect stack 152 can be formed on the front side (surface) of semiconductor substrate 150 (see, e.g., FIG. 7E). Prior to the frontside processing of wafer 106, semiconductor substrate 150 may be attached to p+ silicon layer 310. Substrate layer 150 may be an epitaxial silicon layer. TSV structures 160 can be formed at least partially through epitaxial silicon layer 150 and interconnect stack 152. Although the operations of block 410 are shown to occur after the operations of blocks 400-408, block 410 can alternatively occur before or in parallel (simultaneously) with any of blocks 400-408.

During the operations of block 412, sensor wafer 106 can be bonded to the back side of analog high voltage wafer 104. The result of block 412 can be shown in FIG. 7F, where wafers 104 and 106 are attached at hybrid bonding interface 105.

During the operations of block 414, the back side of sensor wafer 106 can be processed. For example, the p+ silicon layer 310 of FIG. 7F can be removed via a mechanical grinding and/or a wet etch process. Thereafter, a planarizing process such as a chemical mechanical polishing (CMP) process can be used to polish down the back side of substrate layer 150 to reveal the TSV structures 160. After the CMP or other planarization process, passivation layer 170 can be formed on the back surface of substrate layer 150 (see operations of block 416). Passivation layer 170 is sometimes referred to as a BSI passivation layer. Additional processing steps can then occur to selectively pattern passivation layer 170 and to form contact pads 172 that are coupled to one or more TSV structures 160 (see operations of block 418).

The operations of FIG. 8 are illustrative. In some embodiments, one or more of the described operations may be modified, replaced, or omitted. In some embodiments, one or more of the described operations may be performed in parallel. In some embodiments, additional processes may be added or inserted between the described operations. If desired, the order of certain operations may be reversed or altered and/or the timing of the described operations may be adjusted so that they occur at slightly different times.

The embodiments above described in connection with FIGS. 3-8 in which the high voltage devices in the analog die 104 includes both n-type devices N1 and p-type devices P1 are exemplary. FIG. 9 shows another embodiment of SPAD circuitry 100′ that includes high voltage p-type devices P1 but does not include any high voltage n-type devices N1. As shown in FIG. 9, the analog high voltage wafer 104 has a p-type vertical transistor P1 formed as part of each SPAD pixel 30 but does not include any n-type vertical transistor N1 (see lack of transistor N1). This can help save one or more processing steps when fabricating wafer 104. The remaining structure of the entire wafer stack is similar or identical to that already described in connection with FIGS. 4-8 and need not be reiterated in detail to avoid obscuring the present embodiments.

Various embodiments of SPAD circuitry are included. An aspect of the disclosure provides circuitry that includes a first die having a plurality of single-photon avalanche diodes (SPADs), where each SPAD in the plurality of SPADs has an anode terminal configured to receive a bias voltage and a cathode terminal, and a second die having a plurality of switches coupled to the cathode terminals of the plurality of SPADs in the first die. The first die can be stacked on a back side of the second die. The first die can include a first semiconductor substrate layer in which the plurality of SPADs are formed, a first interconnect stack of alternating routing and via layers on a front surface of the first semiconductor substrate layer, and a first through silicon via (TSV) extending from a back surface of the first semiconductor substrate layer to the front surface of the first semiconductor substrate layer and at least partially into the first interconnect stack. The second die can include a second semiconductor substrate layer in which the plurality of switches are formed, a second interconnect stack of alternating routing and via layers on a back surface of the second semiconductor substrate layer, a second through silicon via (TSV) extending from the back surface of the second semiconductor substrate layer to a front surface of the second semiconductor substrate layer, and a third interconnect stack of alternating routing and via layers on the front surface of the second semiconductor substrate layer, wherein the second TSV extends at least partially into the third interconnect stack.

The plurality of switches can include p-type transistors having drain terminals coupled to routing structures in the second interconnect stack and having source and gate terminals coupled to routing structures in the third interconnect stack and optionally n-type transistors having drain terminals coupled to the routing structures in the second interconnect stack and having source and gate terminals coupled to the routing structures in the third interconnect stack. The circuitry can include a third die having digital readout logic coupled to the plurality of switches in the second die, where the second die is stacked on a front side of the third die. The third die further can include a third semiconductor substrate layer in which the digital readout logic are formed and a fourth interconnect stack of alternating routing and via layers on a front surface of the third semiconductor substrate layer.

An aspect of the disclosure provides a method that includes forming a first wafer that includes a plurality of single-photon avalanche diodes (SPADs), where each SPAD in the plurality of SPADs has an anode terminal configured to receive a bias voltage and a cathode terminal, forming a second wafer that includes a plurality of switches coupled to the cathode terminals of the plurality of SPADs in the first wafer, and bonding the first wafer to the second wafer. The method can further include forming a third wafer that includes digital readout logic coupled to the plurality of switches in the second wafer and bonding the third wafer to the second wafer. The method can further include forming through silicon via (TSV) structures through a semiconductor substrate layer in the first wafer and forming through silicon via (TSV) structures through a semiconductor substrate layer in the second wafer.

An aspect of the disclosure provides an apparatus that includes a sensor die having a plurality of single-photon avalanche diodes (SPADs), a digital die having digital readout logic powered by a first positive voltage, and an analog die having switches powered by a second positive voltage greater than the first positive voltage, where the analog die is vertically stacked between the sensor die and the digital die. The analog die can have a front side configured to face the digital die and can have a back side configured to face the sensor die. The apparatus can include first through silicon via (TSV) structures in the sensor die and second through silicon via (TSV) structures in the analog die. At least some of the second TSV structures can be coupled to routing structures in the sensor die and to routing structures in the digital die.

The foregoing is merely illustrative and various modifications can be made to the described embodiments. The foregoing embodiments may be implemented individually or in any combination.

What is claimed is:

1. Circuitry comprising:
a first die having a plurality of single-photon avalanche diodes (SPADs), wherein each SPAD in the plurality of SPADs has an anode terminal and a cathode terminal; and
a second die having a plurality of switches coupled to the cathode terminals of the plurality of SPADs in the first die, wherein the first die is stacked on the second die.

2. The circuitry of claim 1, wherein the first die further comprises:
a first semiconductor substrate layer in which the plurality of SPADs are formed;
a first interconnect stack of alternating routing and via layers on a front surface of the first semiconductor substrate layer; and
a first through silicon via (TSV) extending from a back surface of the first semiconductor substrate layer to the front surface of the first semiconductor substrate layer and extending at least partially into the first interconnect stack.

3. The circuitry of claim 2, wherein the first die further comprises:
a passivation layer on the back surface of the first semiconductor substrate layer; and
conductive pads on the passivation layer.

4. The circuitry of claim 2, wherein the plurality of SPADs are configured to receive incoming light from the back surface of the first semiconductor substrate layer.

5. The circuitry of claim 2, wherein the second die further comprises:
a second semiconductor substrate layer in which the plurality of switches are formed;
a second interconnect stack of alternating routing and via layers on a back surface of the second semiconductor substrate layer; and
a second through silicon via (TSV) extending from the back surface of the second semiconductor substrate layer to a front surface of the second semiconductor substrate layer.

6. The circuitry of claim 5, wherein the second die further comprises:
a third interconnect stack of alternating routing and via layers on the front surface of the second semiconductor substrate layer, wherein the second TSV extends at least partially into the third interconnect stack.

7. The circuitry of claim 6, wherein the plurality of switches comprise:
p-type transistors having drain terminals coupled to routing structures in the second interconnect stack and having source and gate terminals coupled to routing structures in the third interconnect stack.

8. The circuitry of claim 7, wherein the plurality of switches further comprise:
n-type transistors having drain terminals coupled to the routing structures in the second interconnect stack and having source and gate terminals coupled to the routing structures in the third interconnect stack.

9. The circuitry of claim 6, further comprising
a third die having digital readout logic coupled to the plurality of switches in the second die, wherein the second die is stacked on the third die.

10. The circuitry of claim 9, wherein the third die further comprises:
a third semiconductor substrate layer in which the digital readout logic are formed; and
a fourth interconnect stack of alternating routing and via layers on a front surface of the third semiconductor substrate layer.

11. A method comprising:
forming a first wafer that includes a plurality of single-photon avalanche diodes (SPADs), wherein each SPAD in the plurality of SPADs has an anode terminal and a cathode terminal;
forming a second wafer that includes a plurality of switches coupled to the cathode terminals of the plurality of SPADs in the first wafer; and
bonding the first wafer to the second wafer.

12. The method of claim 11, further comprising:
forming a third wafer that includes digital readout logic coupled to the plurality of switches in the second wafer; and
bonding the third wafer to the second wafer.

13. The method of claim 12, further comprising:
forming through silicon via (TSV) structures through a semiconductor substrate layer in the first wafer, wherein the TSV structures extend at least partially into an interconnect stack on the semiconductor substrate layer in the first wafer.

14. The method of claim 12, further comprising:
forming through silicon via (TSV) structures through a semiconductor substrate layer in the second wafer, wherein the TSV structures extend at least partially into an interconnect stack on the semiconductor substrate layer in the second wafer.

15. The method of claim 14, further comprising:
forming p-type vertical transistors in the semiconductor substrate layer of the second wafer.

16. The method of claim 15, further comprising:
forming n-type vertical transistors in the semiconductor substrate layer of the second wafer.

17. An apparatus comprising:
a sensor die having a plurality of single-photon avalanche diodes (SPADs);
a digital die having digital readout logic powered by a first positive voltage; and
an analog die having switches powered by a second positive voltage greater than the first positive voltage, wherein the analog die is vertically stacked between the sensor die and the digital die.

18. The apparatus of claim 17, further comprising:
first through silicon via (TSV) structures in the sensor die, wherein at least one of the first TSV structures has a first end coupled to a contact pad and a second end coupled to routing structures in the sensor die.

19. The apparatus of claim 18, further comprising:
second through silicon via (TSV) structures in the analog die, wherein at least one of the second TSV structures has a first end coupled to the routing structures in the sensor die and a second end coupled to routing structures in the digital die.

20. The apparatus of claim 19, wherein at least one of the switches in the analog die has gate and source terminals coupled to the routing structures in the digital die and a drain terminal coupled to the routing structures in the sensor die.
